(19) United States
(12) Patent Application Publication
(10) Pub. No.: US 2009/0278951 A1
(43) Pub. Date: Nov. 12, 2009

(54) Apparatus and methods for multi-sensor synchronization

(75) Inventors: Markus Loose, Thousand Oaks, CA (US); Ying Huang, Newbury Park, CA (US); Giuseppe Rossi, Los Angeles, CA (US); Roberto Marchesini, Santa Monica, CA (US); Gaurang Patel, Newbury Park, CA (US); Qianjiang (Bob) Mao, Chino Hills, CA (US); Gregory Chow, Camarillo, CA (US); John Wallner, Calabasas, CA (US)

Correspondence Address: REED SMITH LLP, 101 Second Street, Suite 1800, SAN FRANCISCO, CA, 94105, US

(73) Assignee: AltaSens, Inc.

(21) Appl. No.: 12/151,917

(22) Filed: May 8, 2008

(51) Int. Cl. H04N 5/228; H04N 5/225; H04N 5/04; H03L 7/00

(52) U.S. Cl. 348/222.1; 348/262; 348/500; 348/540; 348/E05.031; 348/E05.024

(57) ABSTRACT

Apparatus and methods for synchronizing a plurality of image sensors in a video camera system. In one embodiment, a method includes generating a video sync signal, and resetting at least one internal clock divider in each image sensor in synchronization with the video sync signal at the beginning of each video frame. Another embodiment of a method of synchronizing a plurality of image sensors in a video camera system includes detecting a phase state of a signal of at least one internal clock divider in each sensor, wherein the phase state is relative to a system sync signal, and selecting a video output signal for each sensor based on the detected phase state of the at least one internal divider. In a third embodiment, the method includes asserting an asynchronous reset signal, stopping the system clocks in the system, de-asserting the asynchronous reset signal, while the system clocks are stopped, and restarting the system clocks. Each method may be used individually, or the methods can be combined in any combination. A video camera apparatus is also described.

### BACKGROUND OF THE INVENTION

1. Field of the Invention

The present invention relates generally to CMOS image sensors, and more particularly to apparatus and methods for synchronizing multiple image sensors, and for recovering synchronization.

2. Description of the Related Art

Visible imaging systems implemented using CMOS image sensors significantly reduce camera cost and power while improving resolution and reducing noise. The latest cameras use CMOS iSoC sensors that efficiently couple low-noise image detection and processing with a host of supporting blocks on a single chip.

High-performance video cameras are now produced using a multiple CMOS image sensors in a single camera system. For example, advanced video cameras utilize separate sensors for capturing and processing Red, Green and Blue. This provides superior picture quality compared to single sensor systems, but the use of three separate sensors can cause problems due to lack of synchronization between the sensors, especially upon start-up and reset.

The multiple sensors need to start after a reset or powerup sequence with the same understanding of the state of the clock, resets and any internal clock dividers. This is necessary since the video output must be provided by the sensors in a deterministic manner to the electronic components downstream of the sensors (such as a DSP, back-end processor or display).

In some systems, the reset signal could be carefully distributed, much like a clock signal. However, this is difficult to accomplish, and not always possible, especially if the reset signal is generated, for instance, by a processor, which by its nature is operating asynchronously to the sensors.

Another problem with this approach is that that the removal of the reset signal from each sensor must be synchronized with the supplied clock signals. This required synchronization of the removal of the reset signal negates the advantages of having an asynchronous reset signal in the first place.

### SUMMARY OF THE INVENTION

According to one embodiment of the present invention, a video camera system comprises a system video sync signal generator that generates a video sync signal, and a plurality of image sensors, each image sensor having at least one internal clock divider, wherein the video sync signal is applied to the plurality of image sensors to reset the at least one internal clock dividers of each image sensor at the beginning of each video frame in synchronization with the video sync signal. The video sync signal may be a horizontal sync signal, a vertical sync signal, or a combination of the two. The video sync signal may also be applied at the beginning of each line of each video frame.

The video camera system may further comprise a phase state detection circuit, wherein the phase state detection circuit detects a phase state of a signal of the at least one internal clock divider, and a video output signal selection circuit to select a video output signal from an image sensor based on a phase state detected by the phase state detection circuit.

In another embodiment, a video camera system may comprise a system video sync signal generator that generates a video sync signal, a plurality of image sensors, each image sensor having at least one internal clock divider, a phase state detection circuit, wherein the phase state detection circuit detects a phase state of a signal of each of the at least one internal clock divider relative to the video sync signal, and a video output signal selection circuit to select a video output signal from an image sensor based on a phase state detected by the phase state detection circuit.

According to one embodiment of the present invention, a method of synchronizing a plurality of image sensors in a video camera system comprises generating a video sync signal, and resetting at least one internal clock divider in each image sensor in synchronization with the video sync signal at the beginning of each video frame. The video sync signal can be a horizontal sync signal, a vertical sync signal, or a combination of both signals. The video sync signal may be applied at the beginning of each line of each video frame. The method may further comprise detecting a phase state of a signal of the at least one internal clock divider in each sensor, and selecting a video output signal for each sensor based on the detected phase state of the at least one internal divider.

Another method of synchronizing a plurality of image sensors in a video camera system, the method may comprise detecting a phase state of a signal of at least one internal clock divider in each sensor, wherein the phase state is relative to a system sync signal, and selecting a video output signal for each sensor based on the detected phase state of the at least one internal divider.

An additional method of synchronizing a plurality of image sensors in a video camera system according to the present invention comprises asserting an asynchronous reset signal, stopping the system clocks in the system, de-asserting the asynchronous reset signal, while the system clocks are stopped, and restarting the system clocks. The method may further comprise generating a video sync signal, and resetting at least one internal clock divider in each image sensor in synchronization with the video sync signal at the beginning of each video frame. The video sync signal is a horizontal sync signal, a vertical sync signal, or a combination of both signals. The method may further comprise detecting a phase state of a signal of the at least one internal clock divider in each sensor, wherein the phase state is relative to the video sync signal, and selecting a video output signal for each sensor based on the detected phase state of the at least one internal divider. The method may further include detecting a phase state of a signal of the at least one internal clock divider in each sensor, wherein the phase state is relative to the video sync signal, and selecting a video output signal for each sensor based on the detected phase state of the at least one internal divider.

### BRIEF DESCRIPTION OF THE DRAWINGS

The present invention will be readily understood by the following detailed description in conjunction with the accompanying drawings, wherein like reference numerals designate like structural elements, and in which:

FIG. 1 is a block diagram illustrating the distribution of a VSYNC and HSYNC signal to each sensor;

FIG. 2 is a print-out of sample code for utilizing the HSYNC signal to synchronize the multiple sensors according to one embodiment of the present invention;

FIG. 3 is a schematic illustrating the detection of an internal phase and a selection of an appropriate output video signal according to one embodiment of the present invention; and

FIG. 4 is a timing diagram corresponding to the schematic of FIG. 3.

### DETAILED DESCRIPTION OF THE INVENTION

The following description is provided to enable any person skilled in the art to make and use the invention and sets forth the best modes contemplated by the inventor for carrying out the invention. Various modifications, however, will remain readily apparent to those skilled in the art. Any and all such modifications, equivalents and alternatives are intended to fall within the spirit and scope of the present invention.

In a multi-sensor video camera system, it is desirable that the sensors are synchronized such that each sensor outputs the same pixel signal at the same time. Also, it would be desirable for such systems to be able to automatically recover when synchronization is lost during operation, such as might occur due to a noisy electronic environment.

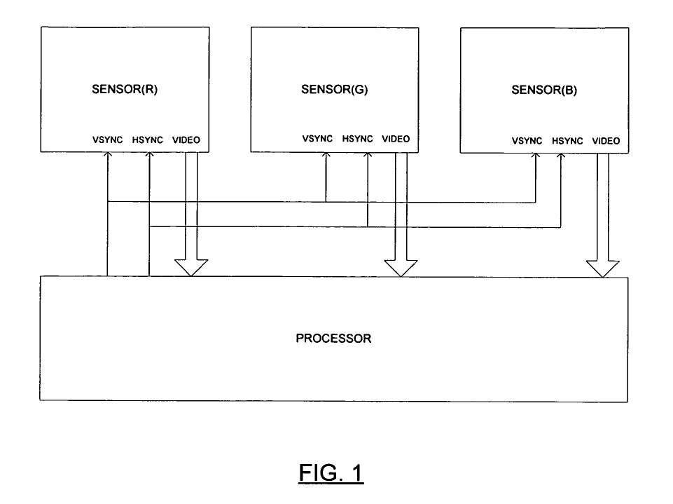

A first embodiment of the present invention is illustrated in FIG. 1. In this approach, the horizontal and/or vertical sync signals from the video timing are used to synchronize the separate sensors. Since these signals must already be carefully synchronized and routed to the various sensors in the system, the signals are readily available.

In this scheme, at the beginning of every frame (or alternately, every valid line within a valid frame), the internal clock dividers of every sensor are reset in synchronization with a sync signal. Preferably the horizontal sync signal is used, but the vertical sync signal could be used instead of, or in addition to, the horizontal sync signal.

By synching the internal clock dividers in each sensor with the horizontal sync signal, it forces the clock phase for each sensor to start at the same time. This procedure guarantees both a valid system start-up, and has the added side benefit of providing system self recovery during operation. If a divider ever goes out of phase, it can be reset and at most only one line of signal data would be lost.

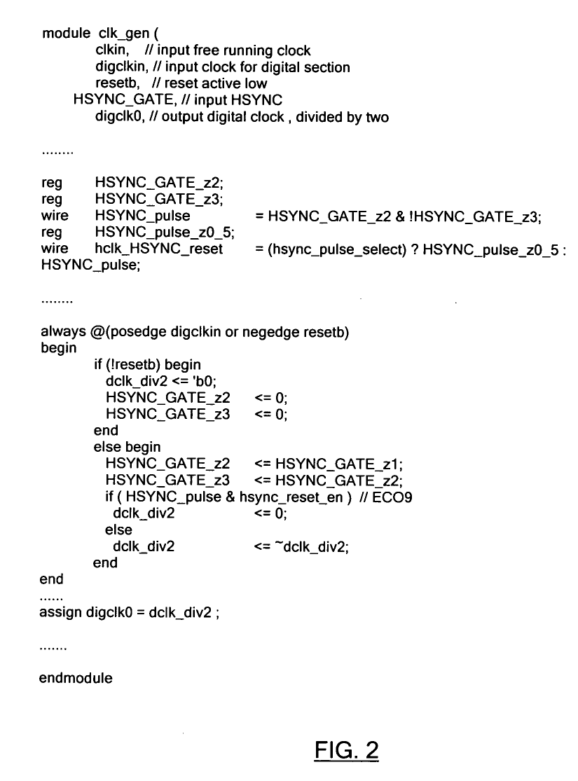

Sample program code for implementing a synchronization scheme based on the HSYNC signal is shown in FIG. 2.

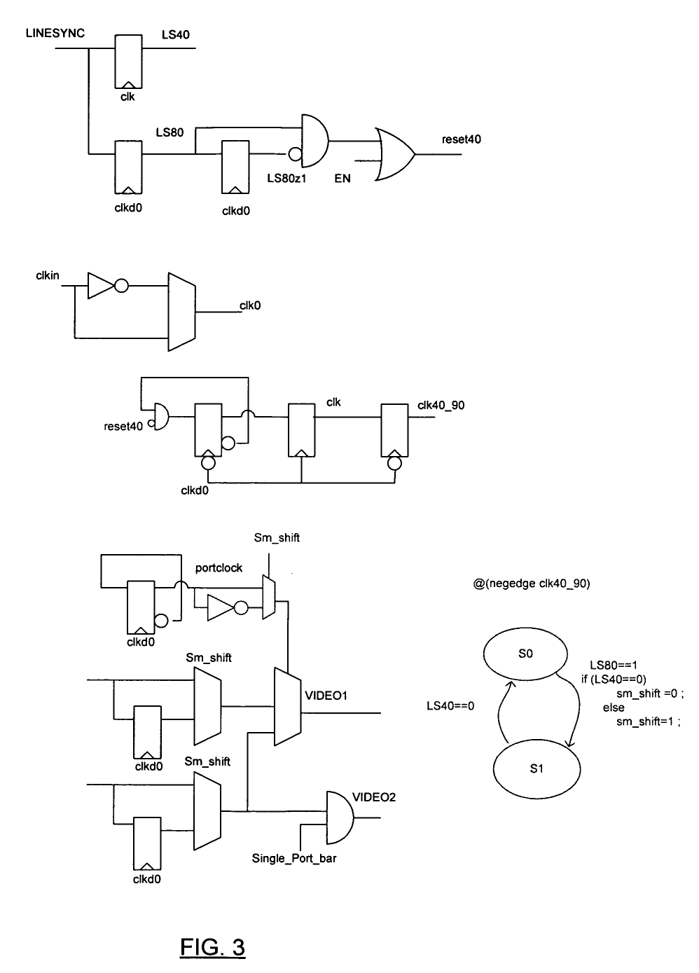

A second embodiment of the present invention is illustrated in FIG. 3. Instead of resetting any internal clock dividers, at the time of a synchronizing event (such a linesync, framesync or a combination of the two), the phase of the internal dividers is sampled, and the video output is shifted as required. In other words, the state of an internal divider is determined. If the state of an internal clock divider is not in sync with the system, then the output signal of the sensor is advanced or retarded by half a clock cycle, so that the output signal is properly synchronized, even though the internal clock divider is not. An appropriate video output signal can thus be selected which has a proper synchronization with respect to the system as a whole. This implementation is particularly useful for a video system having a 720 p HD format, which utilizes an odd number of clock cycles per line.

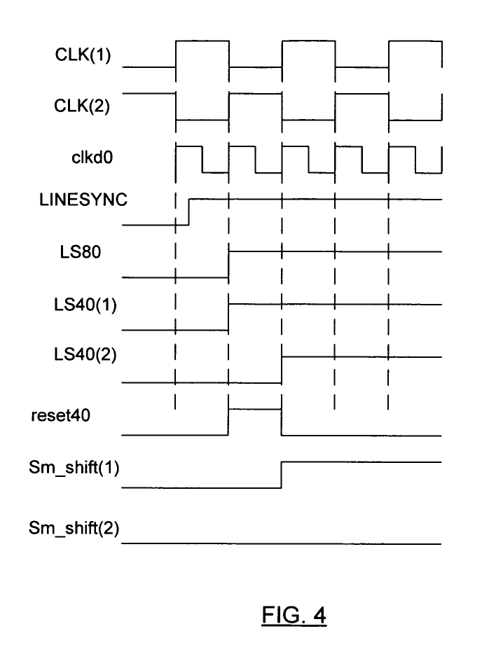

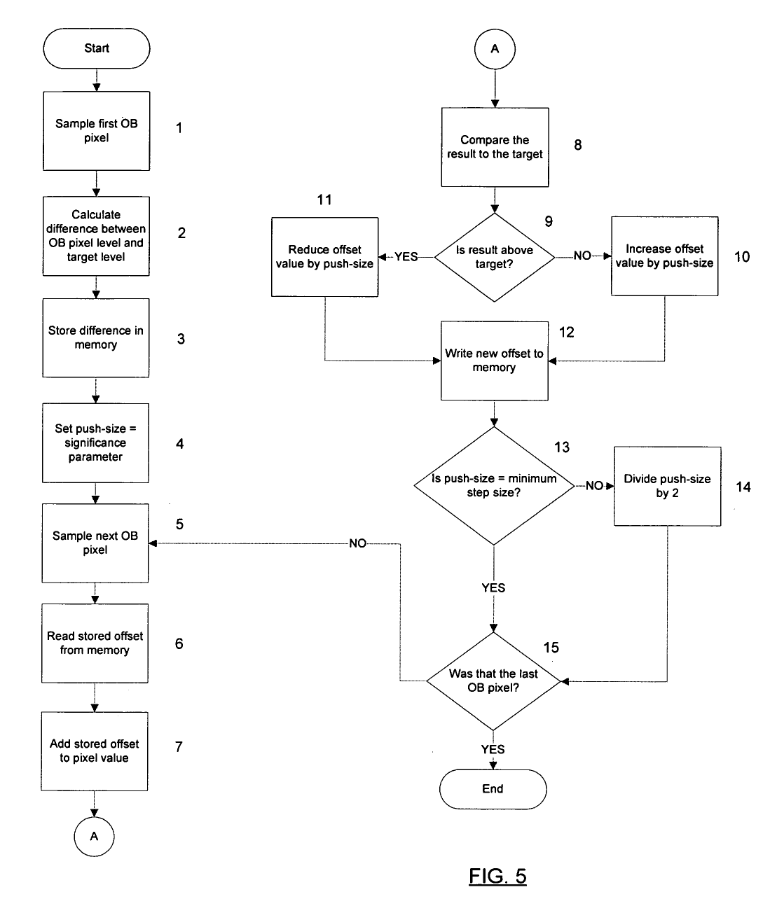

A sample timing diagram is shown in FIG. 4, illustrating the timing of the logic shown in FIG. 3. Using this technique, the video output of each sensor is synchronized, even though the clock states of the sensors may be out of sync. This procedure also provides synchronization recovery.

In certain situations it may be desirable to guarantee a robust start-up sequence, which does not require using other signals. Accordingly, a method for providing synchronization between multiple sensors according to an embodiment of the present invention has the following steps:

Step 1: start clocks (optional)

Step 2: assert asynchronous reset

Step 3: stop clocks

Step 4: de-assert asynchronous reset

Step 5: start clocks

The procedure guarantees that no clocks are running during the critical time period when the asynchronous reset signal is being de-asserted. Note that Step 5 (start clocks) requires that all system clocks be restarted at the same time, and be distributed properly between the sensors. This does not provide a significant design burden, since these clocks are designed to be properly balanced and distributed anyway.

Depending upon the precise requirements of a given system, the above procedures may combined in a single system to provide redundant synchronization between the multiple sensors.

Portions of the present invention may be conveniently implemented using a conventional general purpose or a specialized digital computer or microprocessor programmed according to the teachings of the present disclosure, as will be apparent to those skilled in the computer art.

Appropriate software coding can readily be prepared by skilled programmers based on the teachings of the present disclosure, as will be apparent to those skilled in the software art. The invention may also be implemented by the preparation of application specific integrated circuits or by interconnecting an appropriate network of conventional component circuits, as will be readily apparent to those skilled in the art based on the present disclosure.

Those skilled in the art will appreciate that various adaptations and modifications of the just described preferred embodiments can be configured without departing from the scope and spirit of the invention. Therefore, it is to be understood that, within the scope of the appended claims, the invention may be practiced other than as specifically described herein.

What is claimed is:

1. A video camera system comprising:
a system video sync signal generator that generates a video sync signal; and
a plurality of image sensors, each image sensor having at least one internal clock divider;
wherein the video sync signal is applied to the plurality of image sensors to reset the at least one internal clock dividers of each image sensor at the beginning of each video frame in synchronization with the video sync signal.

2. The video camera system of claim 1, wherein the video sync signal is one of a horizontal sync signal and a vertical sync signal.

3. The video camera system of claim 1, wherein the video sync signal comprises a horizontal sync signal a vertical sync signal.

4. The video camera system of claim 1, wherein the video sync signal is applied at the beginning of each line of each video frame.

5. The video camera system of claim 1, further comprising:
a phase state detection circuit, wherein the phase state detection circuit detects a phase state of a signal of the at least one internal clock divider; and
a video output signal selection circuit to select a video output signal from an image sensor based on a phase state detected by the phase state detection circuit.

6. A method of synchronizing a plurality of image sensors in a video camera system, the method comprising:
generating a video sync signal; and
resetting at least one internal clock divider in each image sensor in synchronization with the video sync signal at the beginning of each video frame.

7. The method of claim 6, wherein the video sync signal is one of a horizontal sync signal and a vertical sync signal.

8. The method of claim 6, wherein the video sync signal comprises a horizontal sync signal and vertical sync signal.

9. The method of claim 6, wherein the video sync signal is applied at the beginning of each line of each video frame.

10. The method of claim 6, further comprising:
detecting a phase state of a signal of the at least one internal clock divider in each sensor; and
selecting a video output signal for each sensor based on the detected phase state of the at least one internal divider.

11. A method of synchronizing a plurality of image sensors in a video camera system, the method comprising:
detecting a phase state of a signal of at least one internal clock divider in each sensor, wherein the phase state is relative to a system sync signal; and
selecting a video output signal for each sensor based on the detected phase state of the at least one internal divider.

12. A method of synchronizing a plurality of image sensors in a video camera system, the method comprising:
asserting an asynchronous reset signal;
stopping the system clocks in the system;
de-asserting the asynchronous reset signal, while the system clocks are stopped; and
restarting the system clocks.

13. The method of claim 12, further comprising:
generating a video sync signal; and
resetting at least one internal clock divider in each image sensor in synchronization with the video sync signal at the beginning of each video frame.

14. The method of claim 13, wherein the video sync signal is one of a horizontal sync signal and a vertical sync signal.

15. The method of claim 13, wherein the video sync signal comprises a horizontal sync signal and vertical sync signal.

16. The method of claim 13, wherein the video sync signal is applied at the beginning of each line of each video frame.

17. The method of claim 13 further comprising:
detecting a phase state of a signal of the at least one internal clock divider in each sensor, wherein the phase state is relative to the video sync signal; and
selecting a video output signal for each sensor based on the detected phase state of the at least one internal divider.

18. The method of claim 12 further comprising:
detecting a phase state of a signal of the at least one internal clock divider in each sensor, wherein the phase state is relative to the video sync signal; and
selecting a video output signal for each sensor based on the detected phase state of the at least one internal divider.

19. A video camera system comprising:
a system video sync signal generator that generates a video sync signal;
a plurality of image sensors, each image sensor having at least one internal clock divider;
a phase state detection circuit, wherein the phase state detection circuit detects a phase state of a signal of each of the at least one internal clock divider relative to the video sync signal; and
a video output signal selection circuit to select a video output signal from an image sensor based on a phase state detected by the phase state detection circuit.
